(19) United States
(12) Patent Application Publication
(10) Pub. No.: US 2016/0124214 A1
(43) Pub. Date: May 5, 2016

(54) ELECTROMAGNETIC MEMS DEVICE

(71) Applicant: Intel Corporation, Santa Clara, CA (US)

(72) Inventors: Barak Freedman, Yoknaeam (IL); Nikolai Berkovitch, Haifa (IL); Arnon Hirshberg, D.N. Misgav (IL)

(21) Appl. No.: 14/530,375

(22) Filed: Oct. 31, 2014

(51) Int. Cl. G02B 26/08; B81B 7/02; B81C 1/00; G02B 26/10

(52) U.S. Cl. CPC G02B 26/085; G02B 26/105; B81B 7/02; B81C 1/00523; B81C 1/00174; B81B 2201/042; B81B 2201/038

(57) ABSTRACT

Embodiments of the present disclosure are directed toward techniques and configurations for a magnetic MEMS apparatus that in some instances may comprise a magnetic circuit and a MEMS device. The magnetic circuit may include two magnets that may be disposed on the substantially flat base and magnetized vertically to the base and in opposite directions to each other to produce a substantially horizontal magnetic field between the magnets. The MEMS device may comprise a mirror and a conductor to pass electric current to interact with the magnetic field created by the magnets. The MEMS device may be disposed substantially between the magnets of the magnetic circuit and above a plane formed by top surfaces of the magnets, to provide an unobstructed field of view for the mirror. The MEMS device may include a ferromagnetic layer to concentrate the magnetic field toward the conductor. Other embodiments may be described and/or claimed.

### FIELD

Embodiments of the present disclosure generally relate to the field of opto-electronics, and more particularly, to improving the electromagnetic field for electromagnetic micro-electromechanical system (MEMS) devices.

### BACKGROUND

Micro-electromechanical system (MEMS) devices are widely used as actuators, including magnetic actuators. Most magnetic actuators are based on electromagnetic force, which acts on a conductor with current running across a magnetic field. These actuators may comprise a magnetic circuit to produce the magnetic field and electric circuit to harvest the electromagnetic force by the running current. Typically, magnetic actuators may be realized using permanent magnets to create the magnetic field, and use a conductor coil to run current and displace the actuating element according to the applied electromagnetic force. However, when a magnetic MEMS device is used as a scanning mirror, e.g., in micro-projector system, the magnetic circuit may obstruct light directed at or reflected by the mirror. Also, the magnetic field strength across the conductor coil may not be sufficient to provide the desired rotating moment for the scanning mirror when the current is running through the electric circuit of the device.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example and not by way of limitation in the figures of the accompanying drawings.

FIG. 1 schematically illustrates an example apparatus having a magnetic circuit and a MEMS device in accordance with some embodiments of the present disclosure.

FIG. 2 is a three-dimensional schematic view of an apparatus comprising a magnetic circuit and a MEMS device coupled with the magnetic circuit in accordance with some embodiments.

FIG. 3 is a cross-sectional schematic view of the apparatus of FIG. 2, in accordance with some embodiments.

FIG. 4 illustrates another cross-sectional schematic view of the apparatus of FIG. 2, in accordance with some embodiments.

FIG. 5 illustrates another cross-sectional schematic view of the apparatus of FIG. 2, in accordance with some embodiments.

FIGS. 6-11 illustrate cross-sectional side views of an example MEMS die showing different stages of fabrication of the MEMS device with a ferromagnetic layer, in accordance with some embodiments.

FIG. 12 is a three-dimensional view of an example apparatus comprising a magnetic circuit and a MEMS device configured as discussed in reference to FIGS. 1-4, in accordance with some embodiments.

FIG. 13 is a process flow diagram for a method of fabricating an apparatus comprising a magnetic circuit coupled with a MEMS device, in accordance with some embodiments.

### DETAILED DESCRIPTION

Embodiments of the present disclosure describe techniques and configurations for a MEMS-based apparatus having a magnetic circuit and a MEMS device coupled with the magnetic circuit. The magnetic circuit may include two magnets that may be disposed on a substantially flat base and magnetized substantially vertically to the base and in opposite directions to each other to produce a substantially horizontal magnetic field between the magnets. The MEMS device may comprise a mirror and a conductor to pass electric current to interact with the magnetic field created by the magnets, which may pass the conductor substantially perpendicularly.

The MEMS device may be disposed substantially between the magnets of the magnetic circuit and above a plane formed by top surfaces of the magnets, to provide an unobstructed field of view (FOV) for the mirror when the MEMS device is tilted in response to application of an electromagnetic force produced by the interaction of the magnetic field with the electric current passing through the conductor.

The MEMS device may further comprise a ferromagnetic layer disposed substantially between a frame formed by the conductor (e.g., driving coil) of the MEMS device, to concentrate the substantially horizontal magnetic field toward the driving coil.

In the following description, various aspects of the illustrative implementations will be described using terms commonly employed by those skilled in the art to convey the substance of their work to others skilled in the art. However, it will be apparent to those skilled in the art that embodiments of the present disclosure may be practiced with only some of the described aspects. For purposes of explanation, specific numbers, materials, and configurations are set forth in order to provide a thorough understanding of the illustrative implementations. However, it will be apparent to one skilled in the art that embodiments of the present disclosure may be practiced without the specific details. In other instances, well-known features are omitted or simplified in order not to obscure the illustrative implementations.

In the following detailed description, reference is made to the accompanying drawings that form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

In various embodiments, the phrase “a first layer formed, deposited, or otherwise disposed on a second layer,” may mean that the first layer is formed, deposited, or disposed over the second layer, and at least a part of the first layer may be in direct contact (e.g., direct physical and/or electrical contact) or indirect contact (e.g., having one or more other layers between the first layer and the second layer) with at least a part of the second layer.

As used herein, the term “module” may refer to, be part of, or include an Application Specific Integrated Circuit (ASIC), an electronic circuit, a processor (shared, dedicated, or group), and/or memory (shared, dedicated, or group) that execute one or more software or firmware programs, a combinational logic circuit, and/or other suitable components that provide the described functionality.

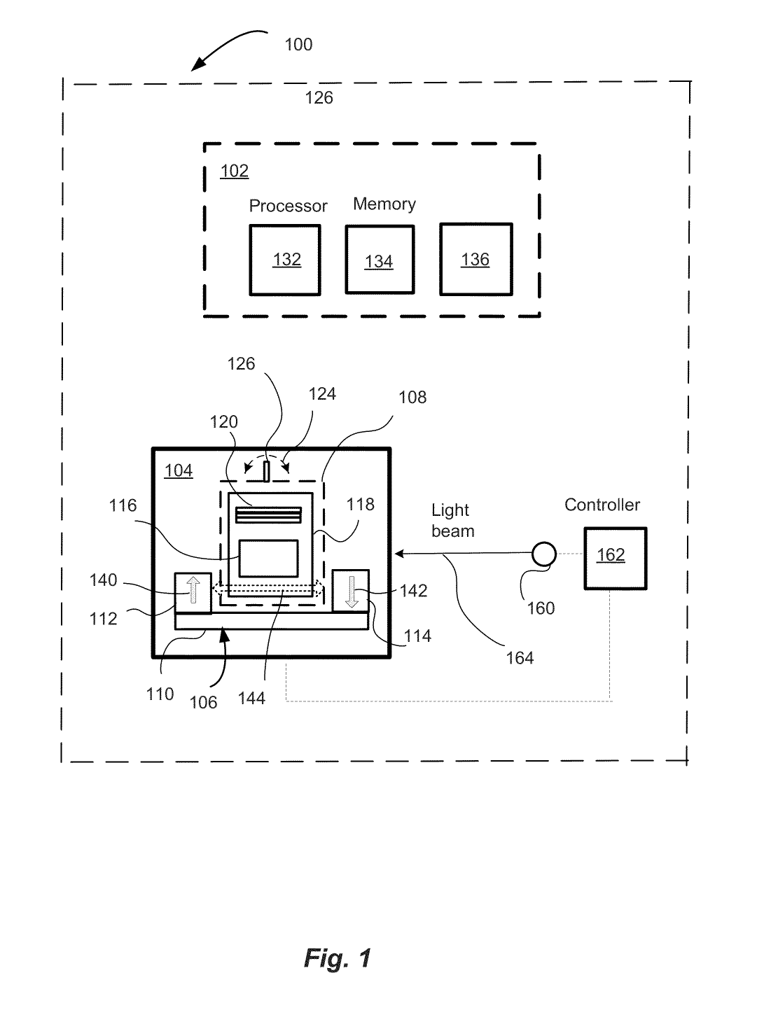

FIG. 1 schematically illustrates an example apparatus 100 in accordance with some embodiments of the present disclosure. In some embodiments, the apparatus 100 may comprise an apparatus for a three-dimensional (3D) object acquisition, such as a 3D scanner, a 3D camera, a game console, or any other device configured for a 3D object acquisition. More generally, the example apparatus 100 may comprise any apparatus that may employ a MEMS device described herein. In some embodiments, as illustrated, the device 100 may include a data processing module 102 and an optical scanner module 104 coupled with the data processing module 102.

The data processing module 102 may comprise a number of components. The components may include a processor 132, coupled with a memory 134 configured to enable the above-noted and other functionalities of the apparatus 100. For example, the processor 132 may be configured with executable instructions stored in the memory 134 to enable operations of the optical scanner module 104. In some embodiments, the data processing module 102 may further include additional components 136 that may be necessary for operation of the apparatus 100, but are not the subject of the present disclosure. For example, the processor 132, the memory 134, and/or other components 136 may comport with a processor-based system that may be a part of, or include, the device 100, in accordance with some embodiments.

The processor 132 may be packaged together with computational logic, e.g., stored in the memory 134, and configured to practice aspects of embodiments described herein, such as optical scanner module 104's operation, to form a System in Package (SiP) or a System on Chip (SoC). The processor 132 may include any type of processors, such as a central processing unit (CPU), a microprocessor, and the like. The processor 132 may be implemented as an integrated circuit having multi-cores, e.g., a multi-core microprocessor. The memory 134 may include a mass storage device that may be temporal and/or persistent storage of any type, including, but not limited to, volatile and non-volatile memory, optical, magnetic, and/or solid state mass storage, and so forth. Volatile memory may include, but is not limited to, static and/or dynamic random-access memory. Non-volatile memory may include, but is not limited to, electrically erasable programmable read-only memory, phase change memory, resistive memory, and so forth.

The optical scanner module 104 may include a magnetic circuit 106 and a MEMS device 108 coupled with the magnetic circuit 106. The magnetic circuit 106 may include a base 110 and first and second magnets 112, 114 disposed on the base 110 opposite each other. As will be described below in greater detail, the first and second magnets 112, 114 may be magnetized substantially vertically to the base and in opposite directions to each other (as indicated by arrows 140, 142) to produce a substantially horizontal magnetic field 144 between the first and second magnets 112, 114.

The MEMS device 108 may comprise a mirror 116 and a conductor (e.g, driving coil comprising a frame-like shape) 118 to pass electric current to interact with magnetic field created by magnets 112, 114. The substantially horizontal magnetic field 144 produced by the magnetic circuit 106 may pass the conductor 118 substantially perpendicularly, as will be described below.

The MEMS device 108 may further comprise a ferromagnetic layer 120 disposed substantially between the frame formed by the conductor 118 of the MEMS device 108, to concentrate the magnetic field toward the conductor 118. As indicated by arrow 124, the MEMS device 108 may be at least partially rotatable (e.g., tiltable) around axis 126.

The apparatus 100 components (e.g., components 136) may further include a light source 160, such as an optical module configured to transmit and/or receive light. In some embodiments, the optical module may comprise a laser device configured to provide a light beam 164, coupled with a controller 162. In some embodiments, the memory 134 may include instructions that, when executed on the processor 132, may configure the controller 162 to control the light beam 164 produced by the light source 160. Additionally or alternatively, in some embodiments, the memory 134 may include instructions that, when executed on the processor 132, may configure the controller 162 to control current supply to the optical scanner module 104 (e.g., to the conductor 118). In some embodiments, the controller 162 may be implemented as a software component stored, e.g., in the memory 134 and configured to execute on the processor 132. In some embodiments, the controller 162 may be implemented as a combination of software and hardware components. In some embodiments, the controller 162 may include a hardware implementation. The details of the functional implementation of the controller 162 are not the subject of the present disclosure.

The data processing module 102 and optical scanner module 104 may be coupled with one or more interfaces (not shown) configured to facilitate information exchange among the above-mentioned components. Communications interface(s) (not shown) may provide an interface for the apparatus 100 to communicate over one or more wired or wireless network(s) and/or with any other suitable device. In various embodiments, the apparatus 100 may be included or associated with, but is not limited to, a server, a workstation, a desktop computing device, a scanner, a game console, a camera, or a mobile computing device (e.g., a laptop computing device, a handheld computing device, a handset, a tablet, a smartphone, a netbook, an ultrabook, etc.).

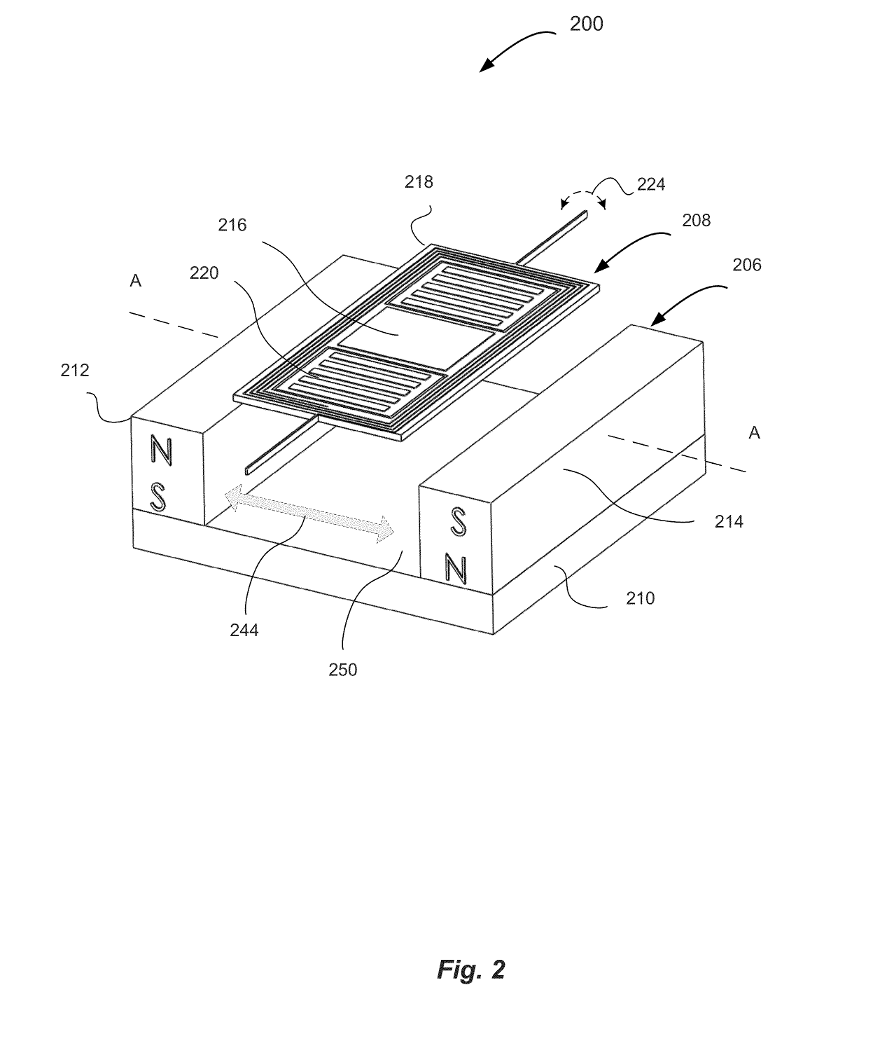

In various embodiments, the apparatus 100 may have more or fewer components, and/or different architectures. For example, in some embodiments, the apparatus 100 may comprise one or more of a camera, a keyboard, display such as a liquid crystal display (LCD) screen (including touch screen displays), a touch screen controller, a non-volatile memory port, an antenna or multiple antennas, a graphics chip, an ASIC, speaker(s), a battery, an audio codec, a video codec, a power amplifier, a global positioning system (GPS) device, a compass, an accelerometer, a gyroscope, and the like. In various embodiments, the apparatus 100 may have more or fewer components, and/or different architectures. In various embodiments, techniques and configurations described herein may be used in a variety of systems that benefit from the principles described herein, such as optoelectronic, electro-optical, MEMS devices (e.g., 108) and systems, and the like. The embodiments of the optical scanner module 104 of the apparatus 100, and more particularly, the embodiments of the magnetic circuit 106 and MEMS device 108 included in the optical scanner module 104 of the apparatus 100, will be described in greater detail in reference to FIGS. 2-12.

FIG. 2 is a three-dimensional schematic view of an apparatus 200 comprising a magnetic circuit and a MEMS device coupled with the magnetic circuit in accordance with some embodiments. The magnetic circuit and the MEMS device may be configured similarly to the magnetic circuit 106 and MEMS device 108 of FIG. 1.

More specifically, the apparatus 200 may include the magnetic circuit 206 and a MEMS device 208. The magnetic circuit 206 may include first and second magnets 212, 214 that may be disposed on a base 210 and magnetized substantially vertically to the base 210 and in opposite directions to each other, as indicated by the polarity of magnets shown in FIG. 2. The base 210 may comprise a magnetic material and have a substantially flat surface 250, as shown in FIG. 2.

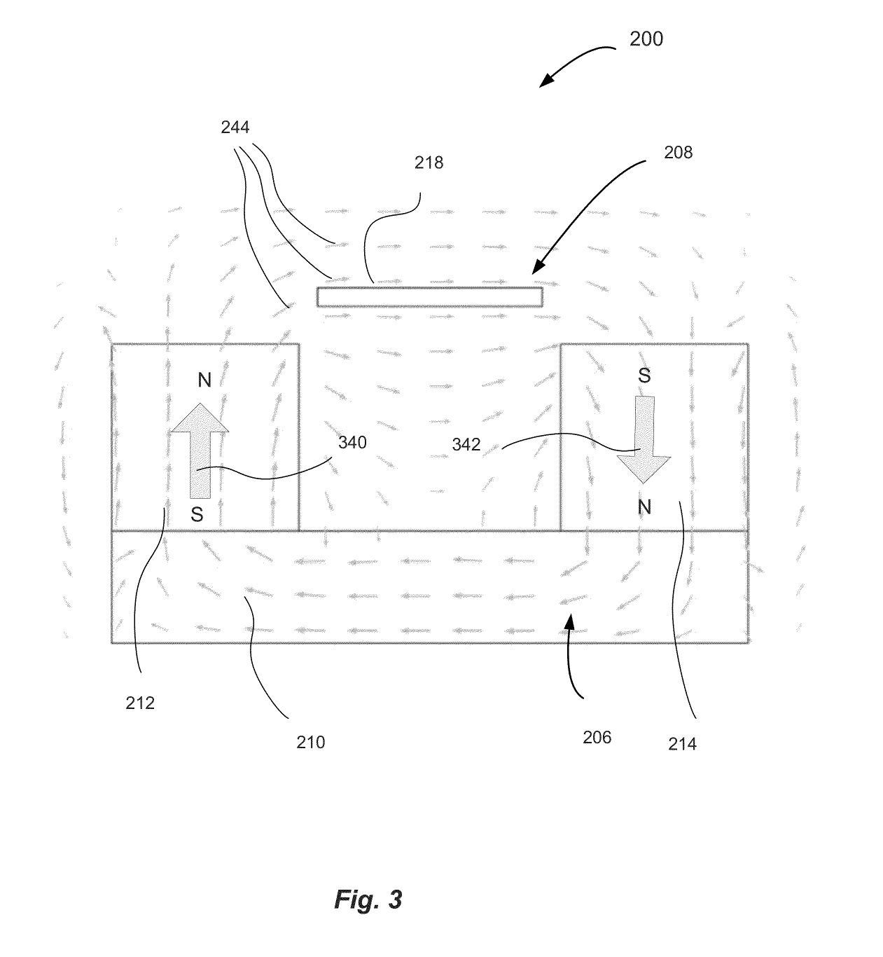

The first and second magnets 212, 214 of the magnetic circuit 206 may comprise permanent magnets having substantially rectangular prismatic shapes, as shown in FIG. 2. Accordingly, when disposed on the substantially flat surface 250 of the base 210, the first and second magnets 212, 214 may produce a magnetic field 244 that may flow substantially horizontally between the magnets 212, 214, as shown in FIG. 3.

FIG. 3 illustrates a cross-sectional schematic view of the apparatus 200 of FIG. 2, in accordance with some embodiments. The cross-section is taken as indicated by dashed line AA in FIG. 2. The magnetic field 244 may be produced (induced) by a combination of the substantially flat base 210 and first and second magnets 212, 214 disposed vertically on the base 210, and having polarity indicated by arrows 340 and 342 and designations “N” and “S.” As shown, the magnetic field 244 may depart, e.g., from North Pole “N” of the first magnet 212, flow substantially horizontally between the first and second magnets 212, 214 and through a conductor 218 of the MEMS device 208, and sump to the South Pole “S” of the second magnet 214. Accordingly, the magnetic field 244 may pass the conductor 218 of the MEMS device 208 substantially perpendicularly.

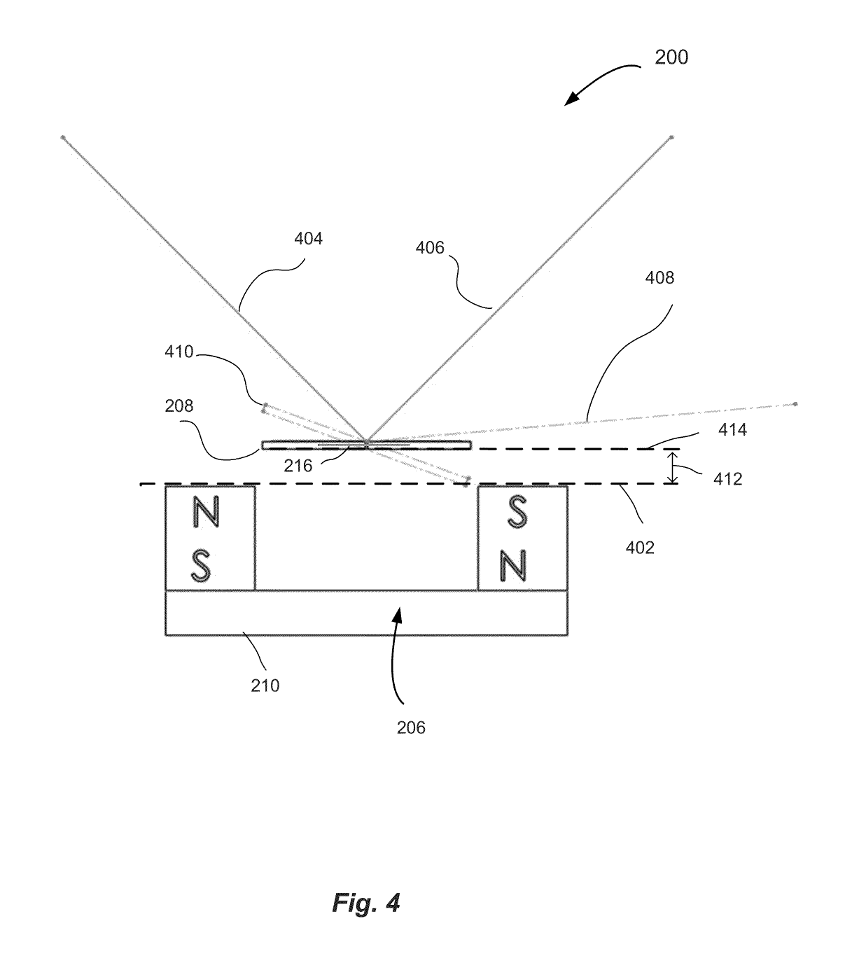

Referring again to FIG. 2, the MEMS device 208 may comprise a mirror 216 and a conductor 218 to pass electric current to interact with the magnetic field 244. The conductor 218 may comprise a driving coil that is looped substantially around the mirror 216, as shown. The MEMS device 208 may be partially rotatable, e.g., tiltable, as indicated by arrow 224. In some embodiments, the MEMS device 208 may be disposed relative to the first and second magnets 212, 214 to provide an unobstructed field of view (FOV) for the mirror 216, as shown in FIG. 4.

FIG. 4 illustrates another cross-sectional schematic view of the apparatus 200 of FIG. 2, in accordance with some embodiments. The cross-section is taken as indicated by dashed line AA in FIG. 2. As shown, the MEMS device 208 may be disposed above a plane 402 formed by the top surfaces of the first and second magnets 212, 214 to provide an unobstructed reflection 406 for a light beam 404 projected to the mirror 216. More specifically, the MEMS device 208 may be disposed above the plane 402 to provide an unobstructed reflection 408 for the light beam 404 projected to the mirror 216, when the mirror 216 may be in a tilted position, as indicated by 410. In other words, MEMS device 208 may be disposed above the plane 402 to provide a distance 412 between the plane 402 and another plane 414 formed by the MEMS device 208 in a non-tilted position relative to the base 210.

Referring again to FIG. 2, the MEMS device 208 may further comprise a ferromagnetic layer 220 disposed substantially between a frame formed by the conductor (driving coil) 218 of the MEMS device 208. The ferromagnetic layer 220 may be used to concentrate the magnetic field 244 toward the conductor (driving coil) 218 as discussed below.

Generally speaking, the ferromagnetic layer 220, when added to the MEMS device 208, may “reshape” the magnetic field 244. The layer 220 may collect and concentrate the surrounding magnetic field 244, aiming it toward the conductor 218 coil. This effect may be enabled because the magnetic field 244 within the apparatus 200 fulfills the boundary conditions for magnetic fields. Adding new boundary conditions or reshaping existing boundary conditions may change the spatial distribution of the existing magnetic field. Following Maxwell equations, the boundary conditions for the static magnetic field of the permanent magnet are:

$$\{ \begin{matrix}\hat{n} \cdot ( {{B}^{⋁}}_{1} - {{B}^{⋁}}_{2} ) = 0 \\ \dot{n} \times ( {{H}^{⋁}}_{1} - {{H}^{⋁}}_{2} ) = 0\end{matrix} = \text{>} \{ \begin{matrix}{{μ}_{1} ( {H}_{⊥} )}_{1} = {{μ}_{2} ( {H}_{⊥} )}_{2} \\ {( {H}_{p} )}_{1} = {( {H}_{p} )}_{2}\end{matrix} \qquad ( 1 )$$

where H is a magnetic field, B=μH is a magnetic induction, and n̂ is a unit normal vector to the boundary surface.

After adding the ferromagnetic material comprising the layer 220 in the plane of the conductor 218 (coil), the initial magnetic field 244 from the permanent magnets 212, 214 induces a magnetic moment within the ferro magnet. Accordingly, a secondary magnetic field is created. A magnetic moment induced by magnets 212, 214 and the secondary field may be aligned in the direction of the original magnetic field 244.

In the steady state, the sum of the original and the secondary fields (the total magnetic field) obeys the continuity of the normal component of magnetic induction and the continuity of the tangential component of the magnetic field (see Equation 1) on the surface of the ferromagnetic material of the layer 220. Magnetic permeability μ of the ferromagnetic material of the layer 220 may be different from magnetic permeability of the surrounding material (e.g., silicon and air); in order to obey the boundary condition, the normal component of the magnetic field is eliminated. In other words, after adding the ferromagnetic material of the layer 220, the direction of the magnetic field 244 near the boundary will be aligned parallel to the ferromagnetic surface of the layer 220. This direction is also a direction that is perpendicular to the conductor 218 (coil). Accordingly, alignment of the magnetic field in this direction enhances the external force (Lorentz force) that may drive (e.g., tilt) the MEMS device 208.

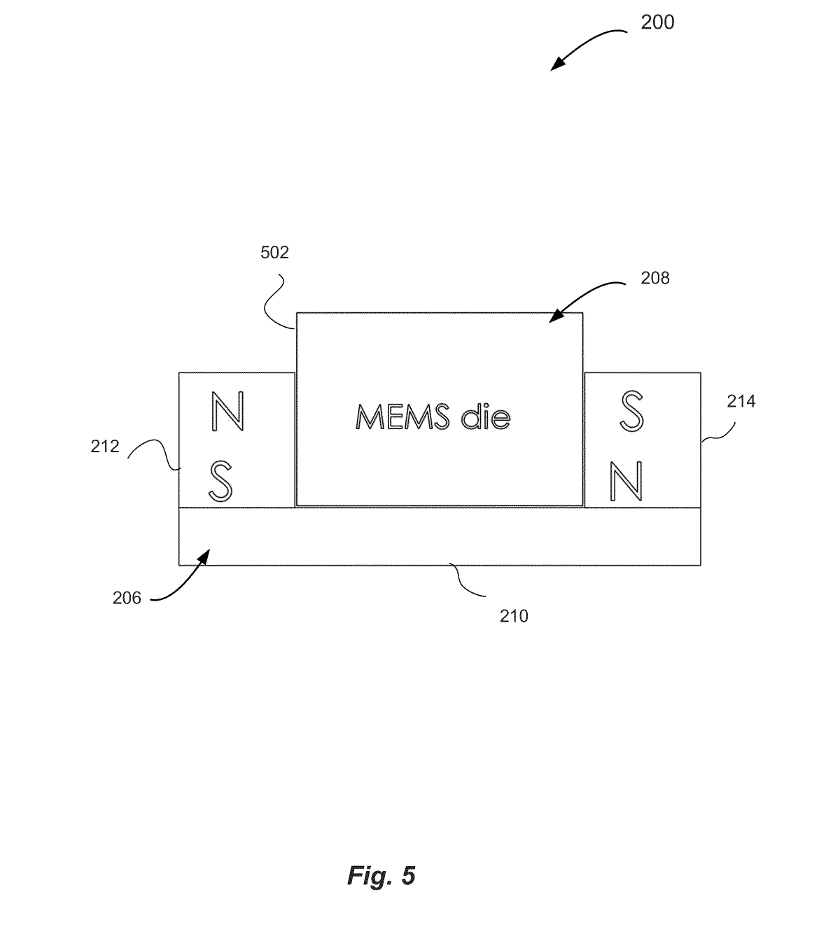

FIG. 5 illustrates another cross-sectional schematic view of the apparatus 200 of FIG. 2, in accordance with some embodiments. The cross-section is taken as indicated by dashed line AA in FIG. 2. As discussed in reference to FIG. 2, first and second magnets 212, 214 of the magnetic circuit 206 may comprise permanent magnets having substantially rectangular prismatic shapes. In embodiments, the MEMS device 208 may comprise a MEMS die forming a MEMS device body 502. In assembly, the first and second magnets 212, 214 may be disposed on the base 210 to have a physical contact with the MEMS device body 502, as shown in FIG. 5.

For example, during assembly, the magnets 212, 214 may be pushed to touch the MEMS device body 502. Effectively, the MEMS device body 502 may be used as a stopper for the magnets 212, 214. Accordingly, geometric dimensions of the MEMS device body 502 may define the disposition of the first and second magnets 212, 214 on the base 210. Because the MEMS device body 502 dimension tolerances are negligible compared to magnets' tolerances (e.g., the body 502 tolerances may be measured on a micron scale), the tolerances related to magnets 212, 214's position on the base 210 may be inherited.

Further, because the magnets 212, 214 may be fixedly attached to the MEMS device body 502, the MEMS device 208 may be positioned substantially equidistant relative to the magnets 212, 214. Therefore, no alignment for the MEMS device 208 may be needed. Accordingly, the assembly of the apparatus 200 comprising the prism-shape magnets 212, 214, the substantially flat base 210, and the MEMS device 208 formed in a MEMS die as shown in FIG. 5 may provide for reduction of assembly tolerances and reduce packaging costs.

It should be noted that FIGS. 2-5 are describing a one dimensional tilting mirror, which may be extended to a two-dimensional scanner, e.g., by applying another two magnets to form a square magnet frame to drive two axes mirror.

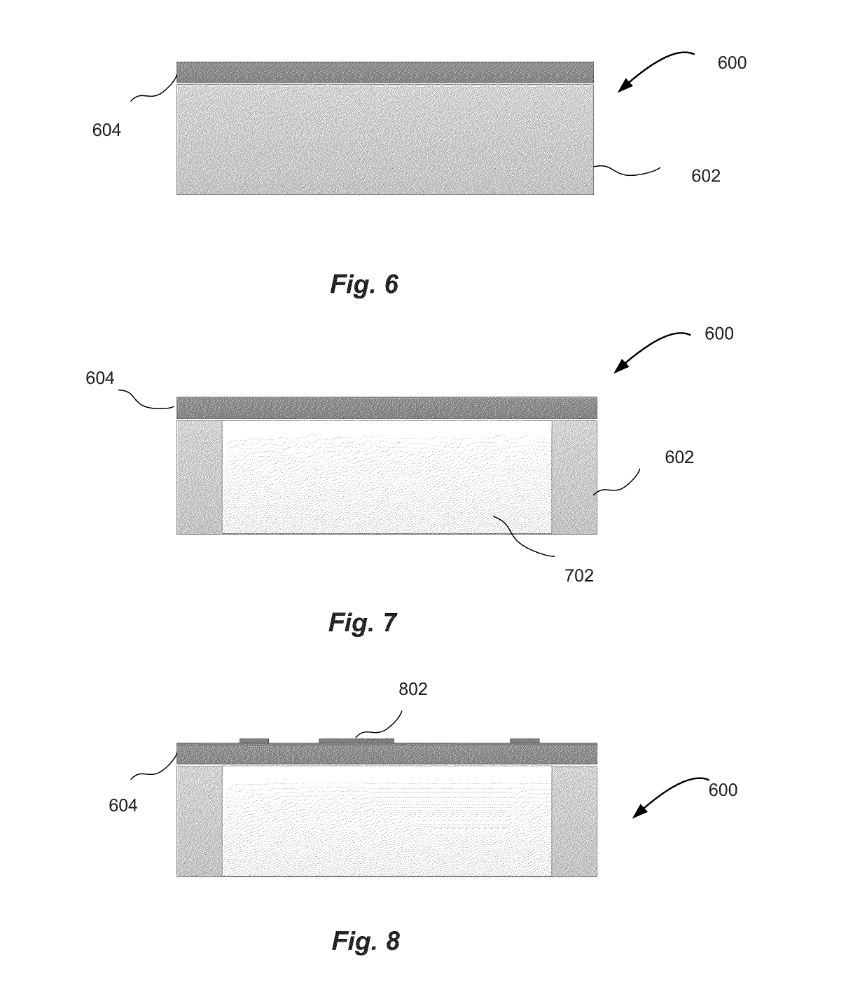

FIGS. 6-11 illustrate cross-sectional side views of an example MEMS die showing different stages of fabrication of the MEMS device with a ferromagnetic layer, in accordance with some embodiments. The MEMS device described in reference to FIGS. 6-11 may be coupled with a magnetic circuit discussed above. More specifically, FIGS. 6-11 illustrate the example MEMS die subsequent to various fabrication operations adapted to form the MEMS device described herein, in accordance with some embodiments. One skilled in the art will appreciate that the fabrication stages of the MEMS device described below are provided for illustrative purposes only; different fabrication processes may be applied to produce the MEMS device as described above in reference to FIGS. 1-5.

FIG. 6 illustrates the MEMS die 600 subsequent to bonding of a device layer 604 (comprising, e.g., silicon material) on a handle layer 602 (comprising, e.g., buried oxide (BOX) layer) of the MEMS die 600. Accordingly, the MEMS die 600 may comprise a silicon on insulator (SOI) wafer, with BOX layer serving as insulator.

FIG. 7 illustrates the MEMS die 600 subsequent to etching away the back side of the handle layer 602 resulting in a hollow space 702, as shown. The back side etching may comprise, for example, a deep reactive iron etching (DRIE) of the handle layer 602.

FIG. 8 illustrates the MEMS die 600 subsequent to a deposition of a metal layer 802 on the device layer 604. The metal layer 802 may include multiple traces comprising a metal, such as gold or aluminum, for example. The metal layer 802 may further include other components, such as resistors and/or transistors as common in the silicon complementary metal-oxide-semiconductor (CMOS) technologies. The metal layer 802 may be deposited on the device layer 604 using lithography, for example. The multiple traces of the metal layer 802 may be used to provide a mirror and driving coil for the MEMS device, as described below in reference to FIG. 11.

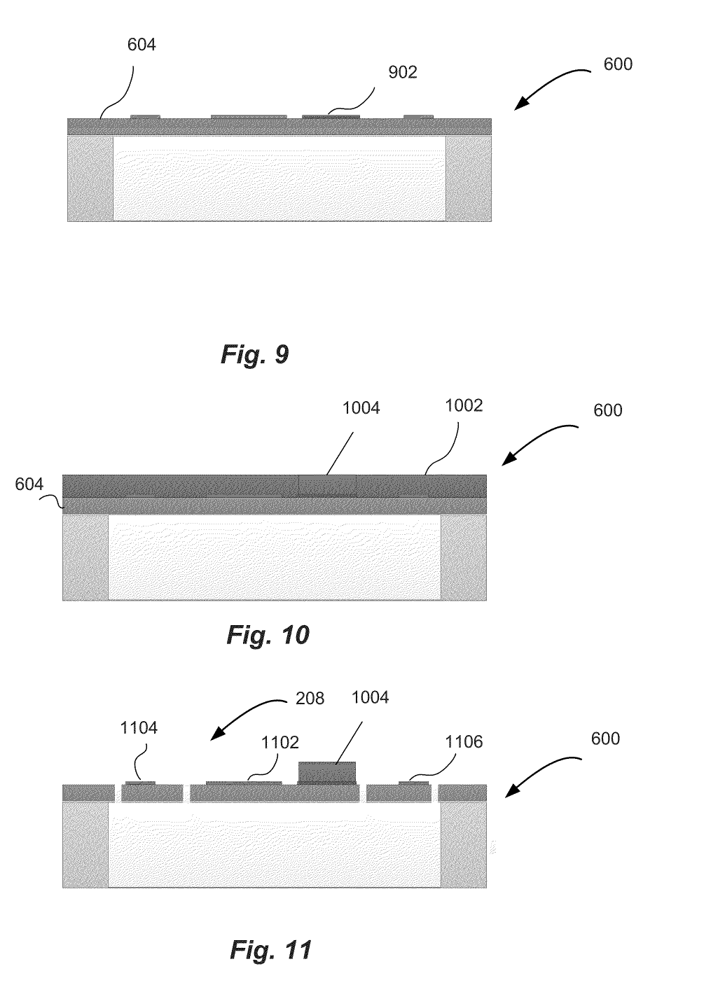

FIG. 9 illustrates the MEMS die 600 subsequent to providing a ferromagnetic seed layer 902 on the device layer 604. The seed layer 902 may be used to grow a ferromagnetic layer, which may reach desired thickness of about 1-30 microns or more if grown on the seed layer 902.

FIG. 10 illustrates the MEMS die 600 subsequent to depositing a mask layer (e.g., photoresist) 1002 on top of the device layer 604 with metal layer 802 and seed layer 902, as shown. The ferromagnetic layer 1002 may be deposited, for example, by growth via electro-less process (e.g., using an electro-less bath). The mask layer 1002 may include a ferromagnetic layer portion 1004 deposited on top of the seed layer 902.

FIG. 11 illustrates the MEMS die 600 subsequent to etching the ferromagnetic layer 1002 and device layer 604 to provide MEMS device topography, including suspending the MEMS device (e.g., on axis) within the MEMS die 600. The resulting MEMS device may comprise the MEMS device 208 and include a mirror 1102, ferromagnetic layer portion 1004, and a frame 1104, 1106 comprising the conductor, such as a driving coil as described above.

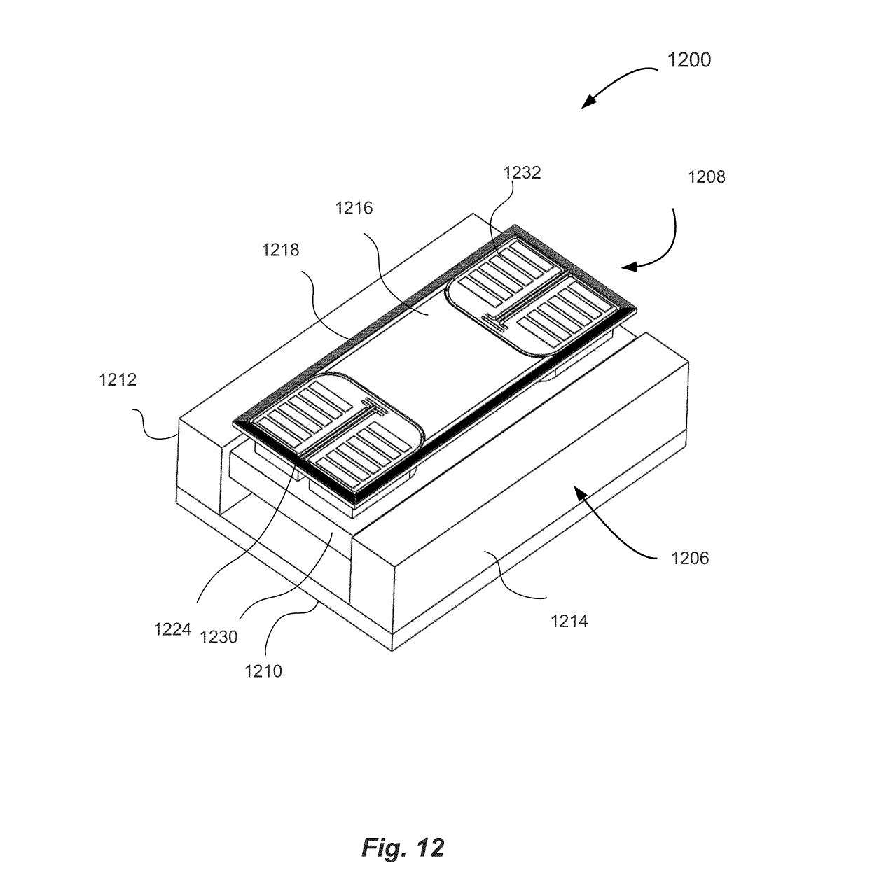

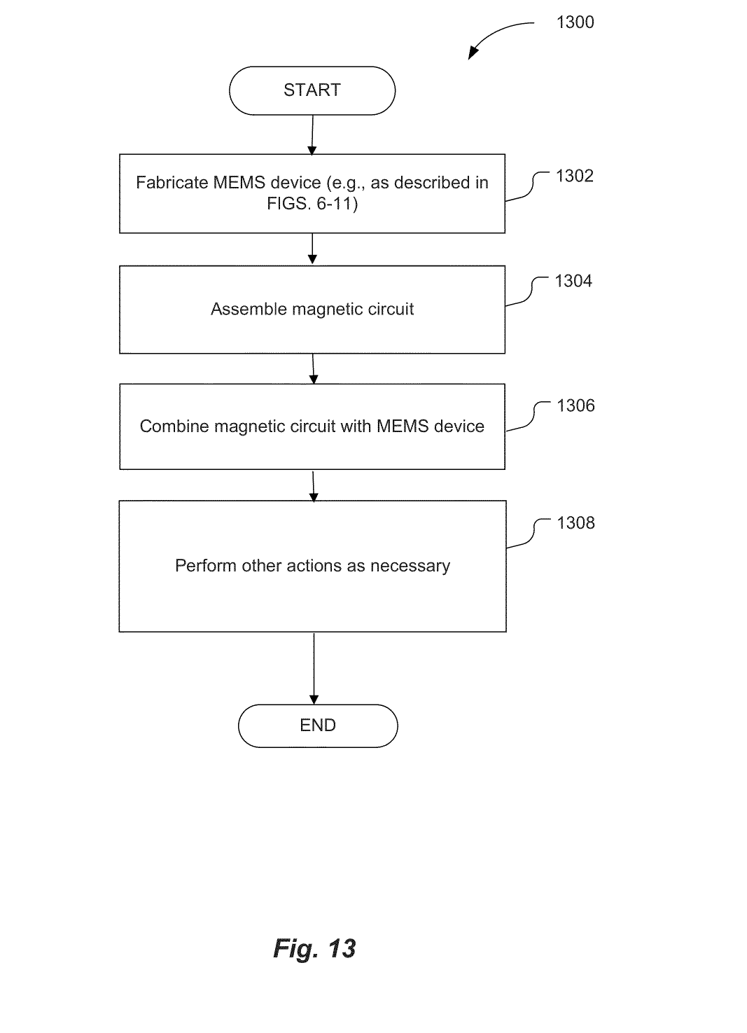

FIG. 12 is a three-dimensional view of an example apparatus 1200 comprising a magnetic circuit and a MEMS device configured as discussed in reference to FIGS. 1-4, in accordance with some embodiments. The assembly of the apparatus 1200 may be provided in accordance with embodiments discussed in reference to FIGS. 5-11. As shown, the apparatus 1200 may comprise a magnetic circuit 1206 and a MEMS device 1208. The magnetic circuit 1206 may include first and second magnets 1212, 1214 that may be disposed on a base 1210 and magnetized substantially vertically to the base 1210 and in opposite directions to each other, as discussed in reference to FIGS. 1-4. The first and second magnets 1212, 1214 of the magnetic circuit 1206 may comprise permanent magnets having substantially rectangular prismatic shapes.

The MEMS device 1208 may comprise a mirror 1216 and a conductor 1218 to pass electric current to interact with a magnetic field induced by the magnetic circuit 1206. The conductor 1218 may comprise a driving coil that may be looped substantially around the mirror 1216, as shown. The MEMS device 1208 may be partially rotatable, e.g., tiltable, and may be suspended using axis 1224, in (or on top of) a MEMS device body 1230. As shown, the MEMS device 1208 may be disposed above the plane of top surfaces of the first and second magnets 1212, 1214 to provide an unobstructed FOV for the mirror 1216.

In some embodiments, the design of the MEMS device 1208 may comprise a frameless design. For example, one or more (e.g., four) posts may connect the device layer 604 (including 1218, 1216, 1232, and 1224) to the MEMS device body 1230. This frameless design may enable a close (short distance) assembly of the magnets (1212, 1214) to the driving coil 1218. This design may provide an advantage because magnetic field may decay exponentially in air gap. As described above, while mirror 1216 is a one dimensional tilting mirror, it may be extended to a two-dimensional scanner mirror, e.g., by applying another two magnets to form a square magnet frame to drive two axes mirror.

The MEMS device 1208 may further include a ferromagnetic layer 1232 disposed in the MEMS device 1208 as described in reference to FIGS. 6-11 and configured to optimize (concentrate) a magnetic field induced by the magnetic circuit 1206 toward the conductor 1218. The MEMS device 1208 may further include other components, for example, contact traces (not shown) configured to provide communicative connection with external devices, such as, for example, controller 162 and/or data processing module 102 described in reference to FIG. 1, and further to enable a provision of electric current to the conductor 1218.

FIG. 13 is a process flow diagram for a method 1300 of fabricating an apparatus comprising a magnetic circuit coupled with a MEMS device, in accordance with some embodiments. The method 1300 may comport with actions described in connection with FIGS. 5-11 in some embodiments. It will be appreciated that the actions described below may not necessarily be taken in the described sequence. Some actions (e.g., described in reference to block 1306) may precede others (e.g., described in reference to blocks 1302, 1304) or take place substantially simultaneously.

At block 1302, a MEMS device may be fabricated according to at least some actions described in reference to FIGS. 6-11. The MEMS device may comprise a mirror and a conductor to pass electric current to interact with a magnetic field induced by a magnetic circuit to be coupled with the MEMS device. The conductor may comprise a driving coil that may be looped substantially around the mirror, as shown. The MEMS device may be partially rotatable, e.g., tiltable, and may be suspended in (or on top of) a MEMS device body.

The MEMS device may further include a ferromagnetic layer disposed in the MEMS device as described in reference to FIGS. 6-11 and configured to optimize (concentrate) the magnetic field induced by the magnetic circuit (when coupled with the MEMS device) toward the conductor. The MEMS device may further include other components configured to provide communicative connection with external devices and further to enable a provision of electric current to the conductor.

At block 1304, a magnetic circuit may be assembled. As described above, the magnetic circuit may comprise first and second magnets that may be disposed on a substantially flat base and magnetized substantially vertically to the base and in opposite directions to each other, as discussed in reference to FIGS. 1-4. Also, the MEMS device body may be bonded to the base.

At block 1306, the magnetic circuit may be combined (coupled) with the MEMS device, to complete fabrication of the apparatus. The magnetic circuit may be coupled with the MEMS device as described in reference to FIG. 5. For example, the magnets of the magnetic circuit may be pushed to touch the MEMS device body, such that the MEMS device body may be used as a stopper for the magnets.

At block 1308, other actions may be performed as necessary. For example, the assembled apparatus may be communicatively coupled with external devices, such as a processing unit and/or other components (e.g., light source) described in reference to FIG. 1.

Various operations are described as multiple discrete operations in turn, in a manner that is most helpful in understanding the claimed subject matter. However, the order of description should not be construed as to imply that these operations are necessarily order dependent. Embodiments of the present disclosure may be implemented into a system using any suitable hardware and/or software to configure as desired.

The embodiments described herein may be further illustrated by the following examples. Example 1 is an apparatus comprising a magnetic circuit including a base and first and second magnets disposed on the base opposite each other, wherein the first and second magnets are magnetized substantially vertically to the base and in opposite directions to each other to produce a substantially horizontal magnetic field between the first and second magnets; and a tiltable micro-electromechanical (MEMS) device disposed substantially between the first and second magnets of the magnetic circuit, wherein the MEMS device comprises a mirror and a conductor to pass electric current to interact with the substantially horizontal magnetic field, wherein the MEMS device is further disposed above a plane formed by top surfaces of the first and second magnets, to provide an unobstructed field of view (FOV) for the mirror when the MEMS device is tilted in response to application of an electromagnetic force produced by interaction of the substantially horizontal magnetic field with the electric current.

Example 2 may include the subject matter of Example 1, and further specifies that the base of the magnetic circuit comprises a magnetic material.

Example 3 may include the subject matter of Example 2, and further specifies that the base of the magnetic circuit comprises a substantially flat surface.

Example 4 may include the subject matter of Example 3, and further specifies that the first and second magnets of the magnetic circuit comprise permanent magnets having substantially rectangular prismatic shapes, to provide the substantially horizontal magnetic field substantially between and above the first and second magnets in response to a disposition on the substantially flat surface of the base.

Example 5 may include the subject matter of Example 4, and further specifies that the MEMS device comprises a MEMS die forming a MEMS device body.

Example 6 may include the subject matter of Example 5, and further specifies that the first and second magnets are disposed on the base to have a physical contact with the MEMS device body, such that geometric dimensions of the MEMS device body define the disposition of the first and second magnets on the base.

Example 7 may include the subject matter of Example 1, and further specifies that the MEMS device is disposed above a plane formed by top surfaces of the first and second magnets to provide an unobstructed FOV comprises the MEMS device disposed above the plane formed by the top surfaces of the first and second magnets to provide an unobstructed reflection for a light beam projected to the mirror in a tilted position.

Example 8 may include the subject matter of Example 7, and further specifies that the MEMS device is disposed above a plane formed by top surfaces of the first and second magnets further comprises the MEMS device disposed above the plane formed by the top surfaces of the first and second magnets to provide a determined distance between the plane formed by top surfaces of the first and second magnets and another plane formed by the MEMS device in a non-tilted position relative to the base.

Example 9 may include the subject matter of any of Examples 1 to 8, and further specifies that the conductor comprises a driving coil that is looped substantially around the mirror and disposed substantially perpendicularly to the substantially horizontal magnetic field passing through the MEMS device substantially above the plane formed by top surfaces of the first and second magnet.

Example 10 may include the subject matter of Example 9, and further specifies that the apparatus further comprises a ferromagnetic layer disposed substantially between a frame formed by the driving coil of the MEMS device, to concentrate the substantially horizontal magnetic field toward the driving coil.

Example 11 may include the subject matter of Example 10, and further specifies that the ferromagnetic layer is to increase strength of the substantially horizontal magnetic field passing substantially perpendicularly through the driving coil.

Example 12 may include the subject matter of Example 1, and further specifies that wherein the MEMS device comprises a frameless device.

Example 13 is an apparatus comprising a data processing module and an optical scanner module coupled with the data processing module, the optical scanner module comprising: a magnetic circuit including a base and first and second magnets disposed on the base opposite each other, wherein the first and second magnets are magnetized substantially vertically to the base and in opposite directions to each other to produce a substantially horizontal magnetic field between the first and second magnets; and a tiltable micro-electromechanical (MEMS) device disposed substantially between the first and second magnets of the magnetic circuit, wherein the MEMS device comprises a mirror and a conductor to pass electric current to interact with the substantially horizontal magnetic field, wherein the MEMS device is further disposed above a plane formed by top surfaces of the first and second magnets, to provide an unobstructed field of view (FOV) for a reflection of a data-carrier light beam directed at the mirror when the MEMS device is tilted in response to application of an electromagnetic force produced by the interaction of the substantially horizontal magnetic field with the electric current.

Example 14 may include the subject matter of Example 13, and further specifies that the base of the magnetic circuit comprises a magnetic material and wherein the base comprises a substantially flat surface.

Example 15 may include the subject matter of Example 14, and further specifies that the first and second magnets of the magnetic circuit comprise permanent magnets having substantially rectangular prismatic shapes, to provide the substantially horizontal magnetic field in response to a disposition on the substantially flat surface of the base.

Example 16 may include the subject matter of Example 15, and further specifies that the first and second magnets are disposed on the base to have a physical contact with a MEMS die comprising a MEMS device body, such that geometric dimensions of the MEMS device body define the disposition of the first and second magnets on the base.

Example 17 may include the subject matter of any of Examples 13 to 16, and further specifies that the conductor comprises a driving coil that is looped substantially around the mirror and disposed substantially perpendicularly to the substantially horizontal magnetic field passing through the MEMS device.

Example 18 may include the subject matter of Example 17, and further specifies that the apparatus further comprises a ferromagnetic layer disposed substantially between a frame formed by the driving coil of the MEMS device, to concentrate the substantially horizontal magnetic field toward the driving coil.

Example 19 may include the subject matter of Example 14, and further specifies that the apparatus comprises a three-dimensional (3D) object acquisition device, wherein the device includes one of a 3D scanner, a 3D camera, a 3D projector, an ultrabook, or a gesture recognition device.

Example 20 is a method of fabricating an electro-magnetic micro-electromechanical systems (MEMS) device, comprising: depositing a semiconductor layer on a handle layer; providing a conductor layer on top of the semiconductor layer; patterning a ferromagnetic layer in the conductor layer; and etching the conductor layer with the patterned ferromagnetic layer to obtain a conductor layer topography comprising a mirror and a conductive coil surrounding the mirror, with the patterned ferromagnetic layer disposed between a frame formed by the conductive coil and adjacent to the mirror.

Example 21 may include the subject matter of Example 20, and further specifies that patterning includes: providing a seed layer; and using an electro-less process to grow the ferromagnetic layer on top of the seed layer.

Example 22 may include the subject matter of Example 20, and further specifies that the method further comprises back-side etching the handle layer to expose the semiconductor layer.

Example 23 may include the subject matter of Example 20, and further specifies that depositing a semiconductor layer on a handle layer comprises disposing a semiconductor layer on a substrate.

Example 24 may include the subject matter of Example 20 to 23, and further specifies that depositing a semiconductor layer comprises depositing a silicon layer, and wherein providing a conductor layer comprises providing one of an aluminum or gold layer.

Various operations are described as multiple discrete operations in turn, in a manner that is most helpful in understanding the claimed subject matter. However, the order of description should not be construed as to imply that these operations are necessarily order dependent. Embodiments of the present disclosure may be implemented into a system using any suitable hardware and/or software to configure as desired.

Although certain embodiments have been illustrated and described herein for purposes of description, a wide variety of alternate and/or equivalent embodiments or implementations calculated to achieve the same purposes may be substituted for the embodiments shown and described without departing from the scope of the present disclosure. This application is intended to cover any adaptations or variations of the embodiments discussed herein. Therefore, it is manifestly intended that embodiments described herein be limited only by the claims and the equivalents thereof.

What is claimed is:

1. An apparatus, comprising:
a magnetic circuit including a base and first and second magnets disposed on the base opposite each other, wherein the first and second magnets are magnetized substantially vertically to the base and in opposite directions to each other to produce a substantially horizontal magnetic field between the first and second magnets; and
a tiltable micro-electromechanical (MEMS) device disposed substantially between the first and second magnets of the magnetic circuit, wherein the MEMS device comprises a mirror and a conductor to pass electric current to interact with the substantially horizontal magnetic field, wherein the MEMS device is further disposed above a plane formed by top surfaces of the first and second magnets, to provide an unobstructed field of view (FOV) for the mirror when the MEMS device is tilted in response to application of an electromagnetic force produced by interaction of the substantially horizontal magnetic field with the electric current.

2. The apparatus of claim 1, wherein the base of the magnetic circuit comprises a magnetic material.

3. The apparatus of claim 2, wherein the base comprises a substantially flat surface.

4. The apparatus of claim 3, wherein the first and second magnets of the magnetic circuit comprise permanent magnets having substantially rectangular prismatic shapes, to provide the substantially horizontal magnetic field substantially between and above the first and second magnets in response to a disposition on the substantially flat surface of the base.

5. The apparatus of claim 4, wherein the MEMS device comprises a MEMS die forming a MEMS device body.

6. The apparatus of claim 5, wherein the first and second magnets are disposed on the base to have a physical contact with the MEMS device body, such that geometric dimensions of the MEMS device body define the disposition of the first and second magnets on the base.

7. The apparatus of claim 1, wherein the MEMS device is disposed above a plane formed by top surfaces of the first and second magnets to provide an unobstructed FOV comprises the MEMS device disposed above the plane formed by the top surfaces of the first and second magnets to provide an unobstructed reflection for a light beam projected to the mirror in a tilted position.

8. The apparatus of claim 7, wherein the MEMS device is disposed above a plane formed by top surfaces of the first and second magnets further comprises the MEMS device disposed above the plane formed by the top surfaces of the first and second magnets to provide a determined distance between the plane formed by top surfaces of the first and second magnets and another plane formed by the MEMS device in a non-tilted position relative to the base.

9. The apparatus of claim 1, wherein the conductor comprises a driving coil that is looped substantially around the mirror and disposed substantially perpendicularly to the substantially horizontal magnetic field passing through the MEMS device substantially above the plane formed by top surfaces of the first and second magnets.

10. The apparatus of claim 9, wherein the apparatus further comprises a ferromagnetic layer disposed substantially between a frame formed by the driving coil of the MEMS device, to concentrate the substantially horizontal magnetic field toward the driving coil.

11. The apparatus of claim 10, wherein the ferromagnetic layer is to increase strength of the substantially horizontal magnetic field passing substantially perpendicularly through the driving coil.

12. The apparatus of claim 1, wherein the MEMS device comprises a frameless device.

13. An apparatus, comprising:
a data processing module and an optical scanner module coupled with the data processing module, the optical scanner module comprising:
a magnetic circuit including a base and first and second magnets disposed on the base opposite each other, wherein the first and second magnets are magnetized substantially vertically to the base and in opposite directions to each other to produce a substantially horizontal magnetic field between the first and second magnets; and
a tiltable micro-electromechanical (MEMS) device disposed substantially between the first and second magnets of the magnetic circuit, wherein the MEMS device comprises a mirror and a conductor to pass electric current to interact with the substantially horizontal magnetic field, wherein the MEMS device is further disposed above a plane formed by top surfaces of the first and second magnets, to provide an unobstructed field of view (FOV) for a reflection of a data-carrier light beam directed at the mirror when the MEMS device is tilted in response to application of an electromagnetic force produced by the interaction of the substantially horizontal magnetic field with the electric current.

14. The apparatus of claim 13, wherein the base of the magnetic circuit comprises a magnetic material and wherein the base comprises a substantially flat surface.

15. The apparatus of claim 14, wherein the first and second magnets of the magnetic circuit comprise permanent magnets having substantially rectangular prismatic shapes, to provide the substantially horizontal magnetic field in response to a disposition on the substantially flat surface of the base.

16. The apparatus of claim 15, wherein the first and second magnets are disposed on the base to have a physical contact with a MEMS die comprising a MEMS device body, such that geometric dimensions of the MEMS device body define the disposition of the first and second magnets on the base.

17. The apparatus of claim 13, wherein the conductor comprises a driving coil that is looped substantially around the mirror and disposed substantially perpendicularly to the substantially horizontal magnetic field passing through the MEMS device.

18. The apparatus of claim 17, wherein the apparatus further comprises a ferromagnetic layer disposed substantially between a frame formed by the driving coil of the MEMS device, to concentrate the substantially horizontal magnetic field toward the driving coil.

19. The apparatus of claim 14, wherein the apparatus comprises a three-dimensional (3D) object acquisition device, wherein the device includes one of a 3D scanner, a 3D camera, a 3D projector, an ultrabook, or a gesture recognition device.

20. A method of fabricating an electro-magnetic micro-electromechanical systems (MEMS) device, comprising:
depositing a semiconductor layer on a handle layer;
providing a conductor layer on top of the semiconductor layer;
patterning a ferromagnetic layer in the conductor layer; and
etching the conductor layer with the patterned ferromagnetic layer to obtain a conductor layer topography comprising a mirror and a conductive coil surrounding the mirror, with the patterned ferromagnetic layer disposed between a frame formed by the conductive coil and adjacent to the mirror.

21. The method of claim 20, wherein patterning includes:
providing a seed layer; and
using an electro-less process to grow the ferromagnetic layer on top of the seed layer.

22. The method of claim 20, further comprising:
back-side etching the handle layer to expose the semiconductor layer.

23. The method of claim 20, wherein depositing a semiconductor layer on a handle layer comprises disposing a semiconductor layer on a substrate.

24. The method of claim 20, wherein depositing a semiconductor layer comprises depositing a silicon layer, and wherein providing a conductor layer comprises providing one of an aluminum or gold layer.
